(19) United States
(12) Patent Application Publication
(10) Pub. No.: US 2012/0199870 A1
(43) Pub. Date: Aug. 9, 2012

(54) ORGANIC LIGHT EMITTING DEVICE

(75) Inventors: Ho-suk Kang, Seoul (KR); Jhun-mo Son, Yongin-si (KR); Hye-yeon Yang, Seoul (KR)

(73) Assignee: SAMSUNG ELECTRONICS CO., LTD., Suwon-si (KR)

(21) Appl. No.: 13/367,718

(22) Filed: Feb. 7, 2012

(30) Foreign Application Priority Data
Feb. 8, 2011 (KR) 10-2011-0011108

(51) Int. Cl. H01L 33/62

(52) U.S. Cl. 257/99; 257/E33.062

(57) ABSTRACT

An organic light emitting device includes a first electrode, a second electrode, an organic emission layer between the first electrode and the second electrode, and an auxiliary electrode in a hole which penetrates the second electrode and the organic emission layer, and exposes the first electrode.

### CROSS-REFERENCE TO RELATED APPLICATION

This application claims priority to Korean Patent Application No. 10-2011-0011108, filed on Feb. 8, 2011, and all the benefits accruing therefrom under 35 U.S.C. §119, the disclosure of which is incorporated herein in its entirety by reference.

### BACKGROUND

1. Field

Provided are organic light emitting devices having a simplified layered structure and increased light extraction efficiency.

2. Description of the Related Art

An organic light emitting device includes an anode, an organic emission layer, and a cathode. When a current flows through the organic emission layer, electrons and holes move to the organic emission layer through an electron transport layer and a hole transport layer, and are recombined with each other so that light is emitted. An anode may be formed of a transparent conductive material that transmits light, for example, indium tin oxide (“ITO”) or indium zinc oxide (“IZO”). However, such a transparent conductive material has a high resistance. Thus, when an area of the anode increases, the resistance increases so that a part near an input terminal of an emission unit has high current density and thus brightness increases. Also, a part of the anode far from the input terminal of the emission unit has low current density and thus brightness decreases. In addition, the current density is high at the part of the anode near a power source input terminal so that the lifespan of a device decreases due to deterioration when the device is driven for a long period of time. In order to solve these problems, a metal having a small resistance, for example, an auxiliary electrode including chromium, molybdenum, or aluminum, is included to reduce the resistance of the transparent conductive material so that an electric characteristic of an organic light emitting device may be improved.

Also, in order to prevent a short between an auxiliary electrode and a cathode, an insulation layer is formed on the auxiliary electrode. However, a manufacturing process becomes complicated due to forming of the insulation layer and a manufacturing cost increases. In addition, light emitted from the organic emission layer may not be emitted to the outside due to the insulation layer, and thus, light extraction efficiency may be deteriorated.

### SUMMARY

Provided are organic light emitting devices having a simplified layered structure.

Provided are organic light emitting devices having increased light extraction efficiency.

Additional aspects will be set forth in part in the description which follows and, in part, will be apparent from the description, or may be learned by practice of the presented embodiments.

Provided is an organic light emitting device which includes: a substrate; a first electrode on the substrate; an organic emission layer on the first electrode; a second electrode on the organic emission layer; a hole which penetrates through the second electrode and the organic emission layer and exposes the first electrode; and an auxiliary electrode in the hole.

The hole may include a first hole portion which penetrates the organic emission layer and a second hole portion which penetrates the second electrode and has a width larger than a width of the first hole portion.

An upper surface of the auxiliary electrode may extend further from the first electrode than an upper surface of the organic emission layer, and a lower surface of the auxiliary electrode contacts the first electrode.

The auxiliary electrode does not overlap the second electrode in a plan view.

The organic light emitting device may further include a protective reflection layer which overlaps the second electrode and the auxiliary electrode.

A lower surface of the auxiliary electrode may contact the first electrode and an upper surface of the auxiliary electrode may be coplanar with an upper surface of the organic emission layer.

The organic light emitting device may further include a protective reflection layer which overlaps the second electrode and the auxiliary electrode.

The protective reflection layer may include an oxide insulation layer, and a metal reflection layer on the oxide insulation layer.

The oxide insulation layer may include at least one selected from the group consisting of a-Si, SiO₂, TiO₂, and MoO.

The auxiliary electrode may include at least one selected from the group consisting of chromium (Cr), molybdenum (Mo), aluminum (Al), calcium (Ca), and nickel (Ni).

The auxiliary electrode may have a cross-section of a square shape, a trapezoid shape, or an inverted trapezoid shape.

The organic emission layer may include a hole injecting layer, a light emission layer, and an electron injecting layer.

### BRIEF DESCRIPTION OF THE DRAWINGS

These and/or other aspects will become apparent and more readily appreciated from the following description of the embodiments, taken in conjunction with the accompanying drawings of which:

FIG. 1 schematically illustrates an organic light emitting device, according to an embodiment of the present invention;

FIG. 2 schematically illustrates an organic light emitting device, according to another embodiment of the present invention;

FIG. 3 schematically illustrates an organic light emitting device, according to another embodiment of the present invention;

FIG. 4 schematically illustrates an organic light emitting device, according to another embodiment of the present invention;

FIG. 5 schematically illustrates an organic light emitting device, according to another embodiment of the present invention; and

FIG. 6 illustrates an emitting area of an organic light emitting device, according to an embodiment of the present invention.

### DETAILED DESCRIPTION

Hereinafter, an organic light emitting device according to one or more embodiments of the present invention will be described in detail with reference to the accompanying drawings. In the drawings, like reference numerals denote like elements and the thicknesses and sizes of elements are exaggerated for clarity. Embodiments are for purposes of describing embodiments and the invention may be embodied in many alternate forms. Like numbers refer to like elements throughout. As used herein, the term “and/or” includes any and all combinations of one or more of the associated listed items. It will be understood that when an element or layer is referred to as being “on” or “formed on,” another element or layer, it can be directly or indirectly formed on the other element or layer.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the invention will be described in detail with reference to the accompanying drawings.

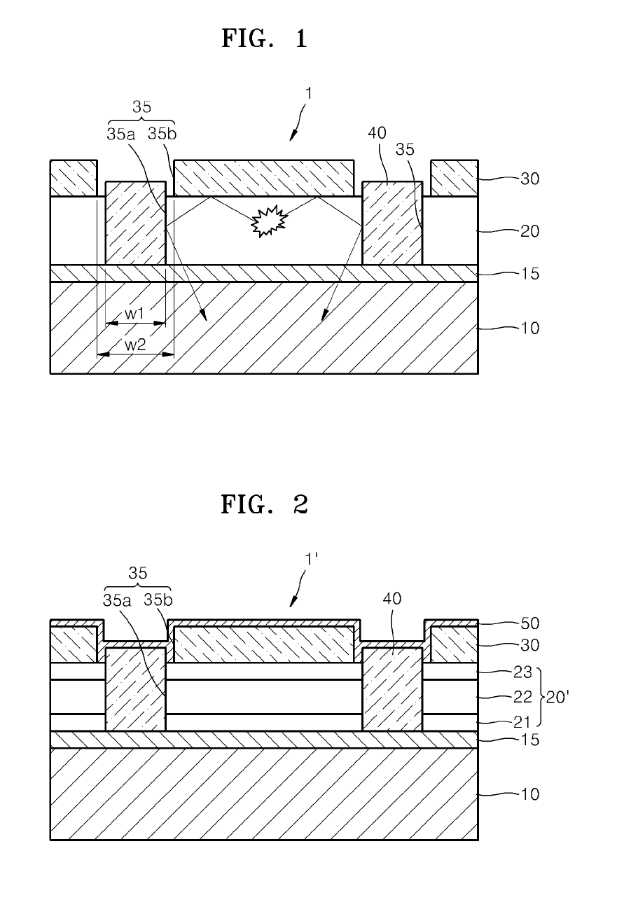

FIG. 1 schematically illustrates an organic light emitting device 1, according to an embodiment of the present invention. The organic light emitting device 1 may include a substrate 10, a first electrode 15 on the substrate 10, an organic emission layer 20 on the first electrode 15, and a second electrode 30 on the organic emission layer 20. The organic light emitting device 1 may include holes 35 that penetrate completely through a thickness of the organic emission layer 20 and the second electrode 30, so as to expose a portion of the first electrode 15. Also, an auxiliary electrode 40 may be in the hole 35.

The substrate 10 may be, for example, a glass substrate, and may transmit light. The first electrode 15 may be an anode. The first electrode 15 may be a transparent electrode that transmits light, and may include a transparent conductive material, for example, indium tin oxide (“ITO”) or indium zinc oxide (“IZO”). The organic emission layer 20 may include an organic compound and may include, for example, a polymer organic compound. The organic emission layer 20 may have a single-layered structure or a multi-layered structure. When the organic emission layer 20 is a multi-layered structure, the organic emission layer 20 may include a hole injecting layer, a light emitting layer, and an electron injecting layer. The organic emission layer 20 of FIG. 1 is a single layer, whereas an organic emission layer of FIG. 2 is a multi-layer. The second electrode 30 may be a cathode.

The hole 35 may include a first hole portion 35a that penetrates completely through the thickness of the organic emission layer 20, and a second hole portion 35b that penetrates completely through the thickness of the second electrode 30. The first hole portion 35a and the second hole portion 35b may form a two-step structure at the boundary therebetween. In the illustrated embodiment, for example, a width w1 of the first hole portion 35a may be smaller than a width w2 of the second hole portion 35b. Here, width w1 of the first hole portion 35a may indicate a width at an upper end of the first hole portion 35a, and width w2 of the second hole portion 35b may indicate a width at a lower end of the second hole portion 35b. The hole 35 may have various forms in a cross-sectional view of the organic light emitting device 1, for example, a longitudinal section of a square shape, a trapezoid shape, or an inverted trapezoid shape.

The auxiliary electrode 40 may be in the hole 35. An entire of the auxiliary electrode 40 may be contained in the hole 35. The auxiliary electrode 40 may include a metal having high electric conductivity. The auxiliary electrode 40 may include at least one selected from the group consisting of chromium (Cr), molybdenum (Mo), aluminum (Al), calcium (Ca), and nickel (Ni). The auxiliary electrode 40 may also include an alloy of the above materials. In an embodiment of forming the organic light emitting device 1, the auxiliary electrode 40 may be formed by using thermal evaporation, sputtering, or printing. The organic emission layer 20 may be formed on a structure, in which the auxiliary electrode 40 is formed, by using a solution process.

The auxiliary electrode 40 may be a single metal layer or a multi-metal layer. As the auxiliary electrode 40 including a metal having high conductivity is included in the organic light emitting device 1, even if the organic light emitting device 1 is manufactured to have a large area, brightness non-uniformity occurring due to an increase in the resistance of the first electrode 15 may be reduced.

A portion of the auxiliary electrode 40 may be in the first hole portion 35a. An upper surface of the auxiliary electrode 40 may be, for example, lower than the upper end of first hole portion 35a, at the same height as the first hole portion 35a, or be higher than the upper end of the first hole portion 35a. In FIG. 1, the upper surface of the auxiliary electrode 40 is higher than the upper end of the first hole portion 35a. That is, the auxiliary electrode 40 may protrude from an upper surface of the organic emission layer 20 so that a lower surface of the auxiliary electrode 40 contacts the first electrode 15 and the upper surface of the auxiliary electrode 40 does not contact the second electrode 30. Here, the auxiliary electrode 40 protrudes from the organic emission layer 20. However, when the first hole portion 35a and the second hole portion 35b have the same width (w1=w2), the auxiliary electrode 40 is only in the first hole portion 35a of the organic emission layer 20, and does not protrude from an upper surface of the organic emission layer 20, so that the auxiliary electrode 40 may not contact the second electrode 30.

In the illustrated embodiment of the present invention, the hole 35 penetrates the organic emission layer 20 and the second electrode 30, and the auxiliary electrode 40 having a relatively large thickness may be in the hole 35. Thus, a current may be uniformly supplied to a first electrode area far from a power source. Also, since the second electrode 30 does not cover (e.g., overlap) the auxiliary electrode 40, an insulation layer is not required to prevent a short from occurring. A form and thickness of the auxiliary electrode 40 are controlled without the insulation layer, and thus, light trapped in the organic emission layer 20 may be reflected so that light extraction efficiency may increase. In addition, a current may be smoothly supplied to a large area and thereby uniform brightness of the organic light emitting device 1 may be provided.

Light is generated from the organic light emitting device 1 as follows. When a voltage is applied to the first electrode 15 and the second electrode 30, electrons and holes are emitted, and the electrons and holes are recombined in the organic emission layer 20, thereby emitting light. Light emitted from the organic emission layer 20 may be emitted to an outside of the organic light emitting device 1 through the first electrode 15. An organic light emitting device may be classified into a top emission structure and a bottom emission structure. The organic light emitting device 1 of FIG. 1 has a bottom emission structure. However, the present invention is not limited thereto and the organic light emitting device may have a top emission structure.

FIG. 2 schematically illustrates an organic light emitting device 1′, according to another embodiment of the present invention. The organic light emitting device 1′ may further include a protective reflection layer 50 covering the second electrode 30 and the auxiliary electrode 40, compared with the organic light emitting device 1. The protective reflection layer 50 may be a single, unitary, continuous member. The protective reflection layer 50 may have a single-layered structure or a multi-layered structure. The protective reflection layer 50 may include, for example, an oxide insulation layer and a metal reflection layer on the oxide insulation layer. In one embodiment, for example, the oxide insulation layer may include at least one selected from the group consisting of a-Si, SiO₂, TiO₂, and MoO. Loss of light emitted between the second electrode 30 and the auxiliary electrode 40 may be reduced by the protective reflection layer 50.

An organic emission layer 20′ may be a multi-layer. In the illustrated embodiment, for example, the organic emission layer 20′ may include a hole injecting layer 21, a light emission layer 22, and an electron injecting layer 23. Also, although not illustrated, the organic emission layer 20′ may further include a hole transfer layer and an electron transfer layer.

In the illustrated embodiment of the present invention, the auxiliary electrode 40 having a relatively large thickness contacts the first electrode 15, but does not contact the second electrode 30 to prevent an electrical short between the auxiliary electrode 40 and the second (cathode) electrode 30. Thus, an electrical current may be uniformly supplied to a first electrode area far from a power source and uniformity of brightness of the organic light emitting device 1 is increased. Additionally, the auxiliary electrode 40 having a relatively large thickness is in the hole 35 which penetrates thicknesses of the organic emission layer 20′ and the second electrode 30, so that light trapped in the organic emission layer 20′ may be reflected and light extraction efficiency is increased.

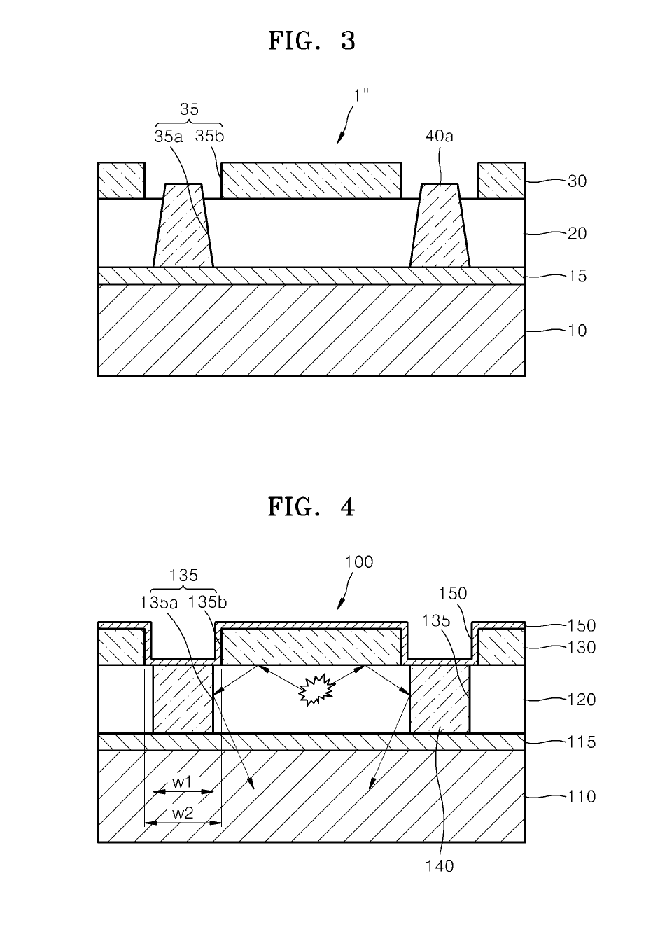

FIG. 3 schematically illustrates an organic light emitting device 1″, according to another embodiment of the present invention. In comparison with the organic light emitting device 1 of FIG. 1, an auxiliary electrode 40a has a trapezoid cross-section. In this case, the first hole portion 35a may have a trapezoid cross-section, and the second hole portion 35b may have a square cross-section. A width of the upper end of the first hole portion 35a may be smaller than a width of the lower end of the second hole portion 35b. Thus, the auxiliary electrode 40a may not come into contact with the second electrode 30, and thus, a short may be reduced or effectively prevented. Additionally, the auxiliary electrode 40a having a relatively large thickness is in the hole 35 which penetrates thicknesses of the organic emission layer 20 and the second electrode 30, so that light trapped in the organic emission layer 20 may be reflected and light extraction efficiency is increased.

FIG. 4 schematically illustrates an organic light emitting device 100, according to another embodiment of the present invention. The organic light emitting device 100 may include a substrate 110, a first electrode 115 on the substrate 110, an organic emission layer 120 on the first electrode 115, and a second electrode 130 on the organic emission layer 120. The organic light emitting device 100 may include holes 135 that penetrate completely through both thicknesses of the organic emission layer 120 and the second electrode 130 so as to expose a portion of the first electrode 115. Also, an auxiliary electrode 140 may be in the hole 135. A form and thickness of the auxiliary electrode 140 may be controlled so that an electrical short between the second electrode 130 and the auxiliary electrode 140 is reduced or effectively prevented. The hole 135 may include a first hole portion 135a that penetrates completely through the thickness of the organic emission layer 120 and a second hole portion 135b that penetrates completely through the thickness of the second electrode 130. In the illustrated embodiment, for example, a width w1 of the first hole portion 135a may be smaller than a width w2 of the second hole portion 135b. Here, the width w1 of the first hole portion 135a may indicate a width of an upper end of the first hole portion 135a, and a width w2 of the second hole portion 135b may indicate a width of a lower end of the second hole portion 135b. The hole 135 may have various forms in a cross-sectional view of the organic light emitting device 100, for example, a longitudinal section of a square form, a trapezoid form, or an inverted trapezoid form.

A shape or dimension of the auxiliary electrode 140 may correspond to the form (e.g., shape or dimension) of the first hole portion 135a. In one embodiment, upper surfaces of the organic emission layer 120 may be coplanar with upper surfaces of the auxiliary electrode 140. That is, a height of the auxiliary electrode 140 may be the same as a height of the first hole portion 135a, where the heights are taken perpendicular to the substrate 110. Also, a protective reflection layer 150 may be on outer or exposed surfaces of the second electrode 130 and the auxiliary electrode 140.

The auxiliary electrode 140 may include at least one selected from the group consisting of chromium (Cr), molybdenum (Mo), aluminum (Al), calcium (Ca), and nickel (Ni). The protective reflection layer 150 may have a single-layered structure and a multi-layered structure. The protective reflection layer 150 may include, for example, an oxide insulation layer and a metal reflection layer on the oxide insulation layer. In one embodiment, for example, the oxide insulation layer may include at least one selected from the group consisting of a-Si, SiO₂, TiO₂, and MoO. Loss of light emitted between the second electrode 130 and the auxiliary electrode 140 may be reduced by the protective reflection layer 150.

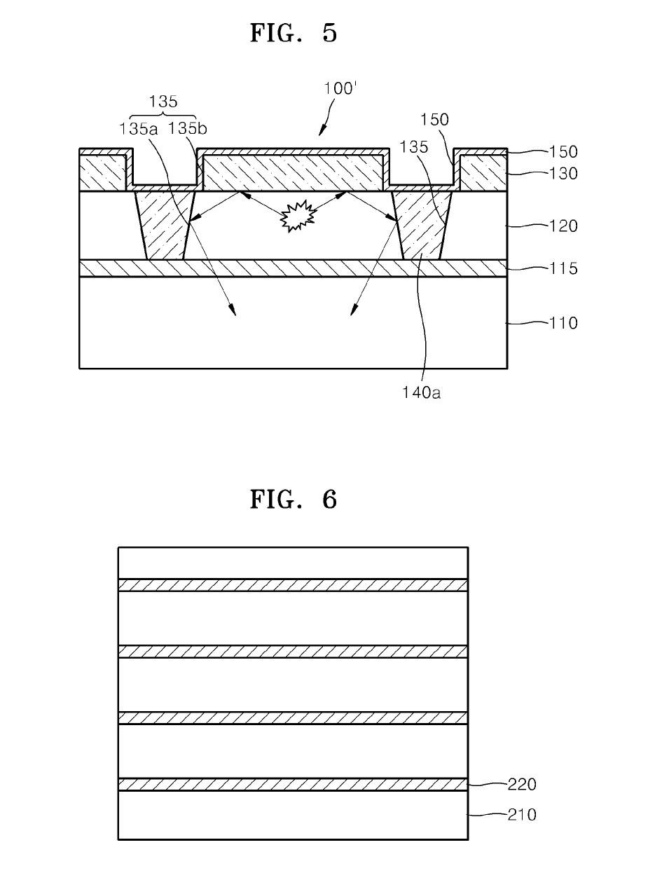

FIG. 5 schematically illustrates an organic light emitting device 100′, according to another embodiment of the present invention. In FIG. 5, a form of an auxiliary electrode 140a is changed from that of the auxiliary electrode 140 in the organic light emitting device 100 of FIG. 4. Like reference numerals in FIGS. 4 and 5 denote like elements, and thus, a detailed description is omitted. The auxiliary electrode 140a has an inverted trapezoid cross-section. The organic light emitting device 100′ may include the first hole portion 135a that penetrates completely through the thickness of the organic emission layer 120 and the second hole portion 135b that penetrates completely through the thickness of the second electrode 130. The auxiliary electrode 140a may have a form corresponding to the first hole portion 135a. The first hole portion 135a may have an inverted trapezoid cross-section, and the second hole portion 135b may have a square cross-section. Also, a width of the first hole portion 135a may be smaller than a width of the second hole portion 135b. The upper surfaces of the organic emission layer 120 may be coplanar with the upper surfaces of the auxiliary electrode 140.

FIG. 6 is a bottom view of an organic light emitting device, according to an embodiment of the present invention. The organic light emitting device may include an emitting area 210 and a non-emitting area 220. The non-emitting area 220 may correspond to an area including an auxiliary electrode. The non-emitting area 220 longitudinally extends in a transverse direction, and FIG. 6 illustrates the organic light emitting device having the auxiliary electrode extending in a transverse direction. When the organic light emitting device according to the illustrated embodiment of the present invention is applied to a lighting apparatus, the emitting area 210 and the non-emitting area 220 may be respectively illuminated in a design defined by a pattern of the auxiliary electrode.

As described above, according to the one or more of the above embodiments of the present invention, when an organic light emitting device is manufactured to have a large area, a size and arrangement interval of the auxiliary electrode are controlled, and thus, uniform brightness may be obtained in a large area. Also, a further insulation layer is not above the auxiliary electrode and an electrical short between the auxiliary electrode and the second electrode may be reduced or effectively prevented, so that a manufacturing process may be simplified, and thereby, a manufacturing cost may be reduced. In addition, as light is reflected by the auxiliary electrode, light extraction efficiency may be increased.

It should be understood that the embodiments described herein should be considered in a descriptive sense only and not for purposes of limitation. Descriptions of features or aspects within each embodiment should typically be considered as referring to other similar features or aspects in other embodiments.

What is claimed is:

1. An organic light emitting device comprising:
a substrate;
a first electrode on the substrate;
an organic emission layer on the first electrode;
a second electrode on the organic emission layer;
a hole which penetrates through the second electrode and the organic emission layer, and exposes the first electrode; and
an auxiliary electrode in the hole.

2. The organic light emitting device of claim 1, wherein the auxiliary electrode does not overlap the second electrode in a plan view.

3. The organic light emitting device of claim 1, wherein the hole comprises:
a first hole portion which penetrates the organic emission layer, and
a second hole portion which penetrates the second electrode and has a width larger than a width of the first hole portion.

4. The organic light emitting device of claim 1, wherein
an upper surface of the auxiliary electrode extends further from the first electrode than an upper surface of the organic emission layer,
a lower surface of the auxiliary electrode contacts the first electrode and
the upper surface of the auxiliary electrode does not contact the second electrode.

5. The organic light emitting device of claim 4, wherein the auxiliary electrode does not overlap the second electrode in a plan view.

6. The organic light emitting device of claim 4, further comprising a protective reflection layer which overlaps the second electrode and the auxiliary electrode.

7. The organic light emitting device of claim 1, wherein
a lower surface of the auxiliary electrode contacts the first electrode, and
an upper surface of the auxiliary electrode is coplanar with an upper surface of the organic emission layer.

8. The organic light emitting device of claim 7, wherein the auxiliary electrode does not overlap the second electrode in a plan view.

9. The organic light emitting device of claim 7, further comprising a protective reflection layer which overlaps the second electrode and the auxiliary electrode.

10. The organic light emitting device of claim 9, wherein the protective reflection layer comprises an oxide insulation layer, and a metal reflection layer on the oxide insulation layer.

11. The organic light emitting device of claim 10, wherein the oxide insulation layer comprises at least one selected from the group consisting of a-Si, SiO₂, TiO₂, and MoO.

12. The organic light emitting device of claim 1, wherein the auxiliary electrode comprises at least one selected from the group consisting of chromium (Cr), molybdenum (Mo), aluminum (Al), calcium (Ca), and nickel (Ni).

13. The organic light emitting device of claim 1, wherein the auxiliary electrode has a cross-section of a square shape, a trapezoid shape, or an inverted trapezoid shape.

14. The organic light emitting device of claim 1, wherein the organic emission layer comprises a hole injecting layer, a light emission layer, and an electron injecting layer.
